(19) United States
(12) Patent Application Publication
(10) Pub. No.: US 2026/0052790 A1
(43) Pub. Date: Feb. 19, 2026

(54) LIGHT DETECTION ELEMENT, IMAGING DEVICE, AND VEHICLE CONTROL SYSTEM

(71) Applicant: SONY SEMICONDUCTOR SOLUTIONS CORPORATION, Kanagawa (JP)

(72) Inventors: Toshiki YAMAMOTO, Nagasaki (JP); Koya TSUCHIMOTO, Nagasaki (JP); Makoto OONO, Nagasaki (JP); Kouichi INOUE, Nagasaki (JP)

(73) Assignee: SONY SEMICONDUCTOR SOLUTIONS CORPORATION, Kanagawa (JP)

(21) Appl. No.: 19/103,162

(22) PCT Filed: Aug. 17, 2023
(86) PCT No.: PCT/JP2023/029676

§ 371 Date: Feb. 11, 2025

(30) Foreign Application Priority Data
Aug. 29, 2022 (JP) 2022-136299

(51) Int. Cl. H10F 39/00

(52) U.S. Cl. CPC H10F 39/8063; H10F 39/8057

(57) ABSTRACT

A light detection element that can suppress a warp in resin, an imaging device, and a vehicle control system. The light detection element includes a semiconductor layer in which a plurality of pixels each including a photoelectric converter is formed, a light shielding structure provided on an outer edge region of the semiconductor layer, a lens resin film stacked on the semiconductor layer and the light shielding structure, and a protective film stacked on the lens resin film. A first region located on an outer edge side and having the light shielding structure, and a second region having the photoelectric converter but not having the light shielding structure are provided. The lens resin film of the first region is formed with at least one of a flat region less in width in a thickness direction than the lens resin film of the second region and an uneven structure.

### TECHNICAL FIELD

The present disclosure relates to a light detection element, an imaging device, and a vehicle control system.

### BACKGROUND ART

In a light detection element such as a complementary metal oxide semiconductor (CMOS) image sensor, light is condensed by an on chip lens (OCL) formed on a light incident surface.

### CITATION LIST

### Patent Document

Patent Document 1: Japanese Patent Application Laid-Open No. 2005-055452

### SUMMARY OF THE INVENTION

### Problems to be Solved by the Invention

In a flat region of the light detection element located outside the region where the on chip lens is formed, there is, however, a possibility that resin will warp due to expansion caused by heat or the like.

It is therefore an object of the present disclosure to provide a light detection element that can suppress a warp in resin, an imaging device, and a vehicle control system.

### Solutions to Problems

In order to solve the above-described problems, the present disclosure provides a light detection element including:
a semiconductor layer in which a plurality of pixels each including a photoelectric converter is formed;
a light shielding structure provided on an outer edge region of the semiconductor layer;
a lens resin film stacked on the semiconductor layer and the light shielding structure; and
a protective film stacked on the lens resin film,
in which a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.

In a case where the lens resin film of the first region includes the uneven structure, a width in the thickness direction of the lens resin film including the uneven structure of the first region may be made less than a width in the thickness direction of the lens resin film including the uneven structure of the second region.

The uneven structure may have a hemispherical structure.

The hemispherical structure may include an on chip lens.

The uneven structure may include a groove.

The lens resin film of the first region may include the flat region and the uneven structure.

The lens resin film of the first region may include the flat region formed on an outer edge side of the uneven structure.

The lens resin film of the first region may include the flat region formed at a side of the second region of the uneven structure.

The flat region and the uneven structure may be formed above the light shielding structure.

The flat region may be formed at a side of the second region of the uneven structure above the light shielding structure.

The flat region may be formed on an outer edge side of the uneven structure above the light shielding structure.

In a case where the lens resin film of the first region includes the flat region, a planar width of the flat region in the lens resin film of the first region may be made less than a planar width excluding a width of the uneven structure of the lens resin film of the second region.

A width in the thickness direction of the lens resin film of the first region may be made greater than a width in the thickness direction of the light shielding structure, and the width in the thickness direction of the light shielding structure may be made greater than a width in the thickness direction of the protective film.

The light shielding structure may include a material having a light shielding characteristic such as a metal film or an organic film, and
the protective film may include an oxide film.

A linear expansion coefficient of the lens resin film of the first region may be different from a linear expansion coefficient of the protective film.

Pixels of the second region may include dummy pixels that are not used for imaging.

Pixels of the first region may include pixels used to acquire information regarding dark current.

In the first region, a planar width of a region that is in contact with the second region may be made less than a planar width on an outer edge side.

In order to solve the above-described problems, the present disclosure may provide an imaging device including:
a light detection element; and
an optical system that condenses light onto the light detection element,
in which the light detection element includes
a semiconductor layer in which a plurality of pixels each including a photoelectric converter is formed,
a light shielding structure provided on an outer edge region of the semiconductor layer,
a lens resin film stacked on the semiconductor layer and the light shielding structure, and
a protective film stacked on the lens resin film,
a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.

In order to solve the above-described problems, the present disclosure provides a vehicle control system including an imaging device.

### BRIEF DESCRIPTION OF DRAWINGS

FIG. 1 is a block diagram illustrating a configuration example of a light detection element according to the present technology.

FIG. 2 is a schematic diagram illustrating an example of a multilayer structure of the light detection element according to the present technology.

FIG. 3 is an enlarged cross-sectional view of a part of a first semiconductor substrate.

FIG. 4 is a diagram schematically illustrating a cause of a warping phenomenon.

FIG. 5 is a diagram illustrating a configuration example 1 of a light detection element 1 intended to reduce stress.

FIG. 6 is a diagram schematically illustrating a top view of the first semiconductor substrate.

FIG. 7 is a diagram illustrating a configuration example 2 of the light detection element.

FIG. 8 is a diagram schematically illustrating a top view of a first semiconductor substrate of the configuration example 2.

FIG. 9 is a diagram illustrating a configuration example 3 of the light detection element intended to reduce force.

FIG. 10 is a diagram schematically illustrating a top view of a first semiconductor substrate of the configuration example 3.

FIG. 11 is a diagram illustrating a configuration example 4 of the light detection element intended to reduce stress.

FIG. 12 is a diagram schematically illustrating a top view of a first semiconductor substrate of the configuration example 4.

FIG. 13 is a diagram illustrating a configuration example 5 of the light detection element 1 intended to reduce stress.

FIG. 14 is a diagram schematically illustrating a top view of a first semiconductor substrate of the configuration example 5.

FIG. 15 is a diagram illustrating a configuration example 6 of the light detection element 1 intended to reduce stress.

FIG. 16 is a diagram schematically illustrating a top view of a first semiconductor substrate of the configuration example 6.

FIG. 17 is a cross-sectional view of an oxide film and a lens resin film during their forming step.

FIG. 18 is a cross-sectional view illustrating a production example 2 of the forming step of forming the oxide film and the lens resin film.

FIG. 19 is a block diagram illustrating an example of a schematic configuration of a vehicle control system.

FIG. 20 is an explanatory diagram illustrating an example of installation positions of an outside-vehicle information detecting section and an imaging section.

### MODE FOR CARRYING OUT THE INVENTION

Hereinafter, embodiments of a light detection element, an imaging device, and a vehicle control system will be described with reference to the drawings. Although main components of the light detection element, the imaging device, and the vehicle control system will be mainly described below, the light detection element, the imaging device, and the vehicle control system may have components and functions that are not illustrated or described. The following description is not intended to exclude components and functions that are not illustrated or described.

### Configuration Example of Light Detection Element

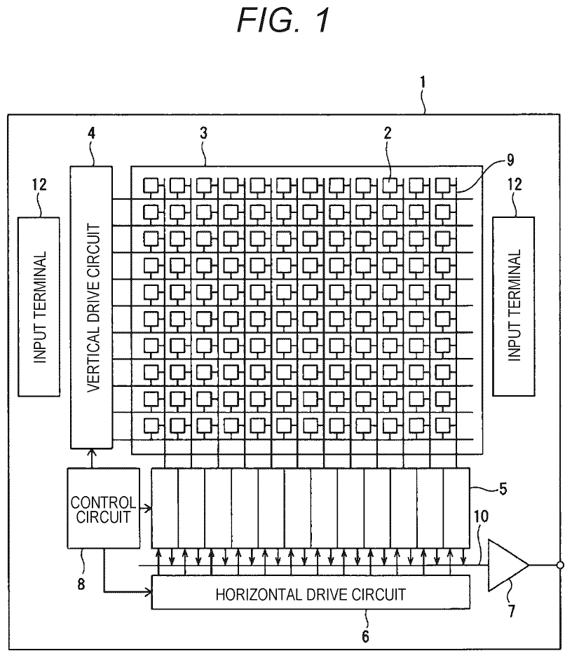

FIG. 1 is a block diagram illustrating a configuration example of a light detection element according to the present technology. As illustrated in FIG. 1, a light detection element 1 is configured as, for example, a complementary metal oxide semiconductor (CMOS) image sensor. The light detection element 1 includes a pixel region (pixel array) 3 in which a plurality of pixels 2 is arranged in a two-dimensional regular array on a semiconductor substrate (for example, Si substrate) (not illustrated), and a peripheral circuit unit.

The pixel 2 includes a photoelectric converter (for example, a photodiode) that performs photoelectric conversion, and a plurality of pixel transistors (MOS transistors). The plurality of pixel transistors may include three transistors, for example, a transfer transistor, a reset transistor, and an amplification transistor. Alternatively, the plurality of pixel transistors may include four transistors by adding a selection transistor. Note that an equivalent circuit of the unit pixel is similar to an equivalent circuit according to a known technology, and thus no detailed description will be given of the equivalent circuit.

Furthermore, the pixel 2 may be configured as one unit pixel or may have a shared pixel structure. This shared pixel structure is a structure in which a plurality of photodiodes shares a floating diffusion and transistors other than a plurality of transfer transistors. That is, in the shared pixel, the photodiodes and the transfer transistors constituting a plurality of unit pixels share another each pixel transistor.

The peripheral circuit unit includes a vertical drive circuit 4, a column signal processing circuit 5, a horizontal drive circuit 6, an output circuit 7, and a control circuit 8.

The vertical drive circuit 4 includes a shift register, for example. The vertical drive circuit 4 selects a pixel drive wiring, and supplies a pixel driving pulse to the selected pixel drive wiring to drive pixels row by row. That is, the vertical drive circuit 4 selectively scans each pixel 2 of the pixel region 3 sequentially in a vertical direction row by row. Then, the vertical drive circuit 4 supplies a pixel signal based on a signal charge generated according to the amount of received light in the photoelectric converter of each pixel 2 to the column signal processing circuit 5 through a vertical signal line 9.

The column signal processing circuit 5 is arranged for each column of the pixels 2, for example. The column signal processing circuit 5 performs signal processing such as noise removal on the signals output from the pixels 2 of one row for each pixel column. Specifically, the column signal processing circuit 5 performs signal processing such as correlated double sampling (CDS) for removing pixel 2-specific fixed pattern noise, signal amplification, and analog/digital (A/D) conversion. A horizontal selection switch (not illustrated) is provided at an output stage of the column signal processing circuit 5 and connected to a horizontal signal line 10.

The horizontal drive circuit 6 includes a shift register, for example. This horizontal drive circuit 6 sequentially selects each of the column signal processing circuits 5 by sequentially outputting horizontal scanning pulses to cause each of the column signal processing circuits 5 to output a pixel signal to the horizontal signal line 10.

The output circuit 7 performs signal processing on signals sequentially supplied from each of the column signal processing circuits 5 through the horizontal signal line 10 and outputs processed signals. For example, the output circuit 7 may perform only buffering, or may perform black level adjustment, column variation correction, various types of digital signal processing, and the like.

The control circuit 8 receives an input clock and data giving a command of an operation mode and the like and outputs data of internal information and the like of the light detection element 1. Furthermore, the control circuit 8 generates a clock signal and a control signal serving as a reference for the operation of the vertical drive circuit 4, the column signal processing circuit 5, the horizontal drive circuit 6, and the like on the basis of a vertical synchronization signal, a horizontal synchronization signal, and a master clock. Then, the control circuit 8 inputs these signals to the vertical drive circuit 4, the column signal processing circuit 5, the horizontal drive circuit 6, and the like. An input/output terminal 12 exchanges signals with the outside.

### Example of Multilayer Structure of Light Detection Element

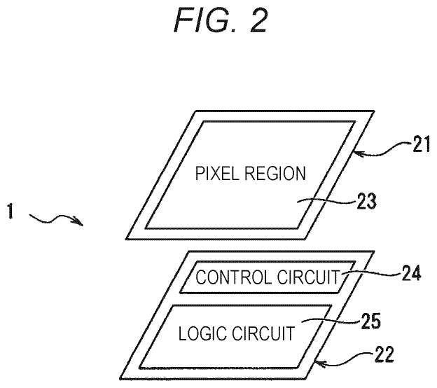

FIG. 2 is a schematic diagram illustrating an example of a multilayer structure of the light detection element according to the present technology. The light detection element 1 illustrated in FIG. 2 includes a first semiconductor substrate 21 and a second semiconductor substrate 22. A pixel region 23 is mounted on the first semiconductor substrate 21. A control circuit 24 and a logic circuit 25 including a signal processing circuit are mounted on the second semiconductor substrate 22. Then, the first semiconductor substrate 21 and the second semiconductor substrate 22 are electrically connected to each other, thereby forming the light detection element 1 as one semiconductor chip. Note that the example of the multilayer structure according to the present embodiment is only illustrative and is not restrictive. For example, a configuration region of the control circuit 24 may be formed in the first semiconductor substrate 21.

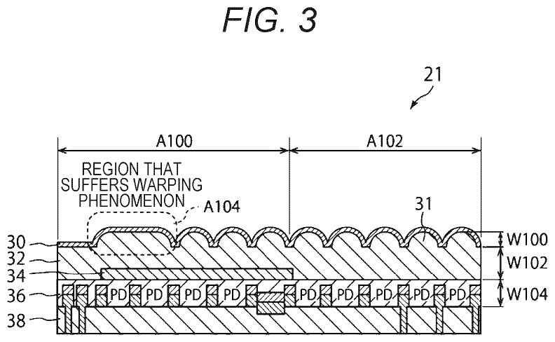

FIG. 3 is an enlarged cross-sectional view of a part of the first semiconductor substrate 21. The light detection element 1 according to the present technology is configured as, for example, a back-illuminated CMOS imaging device. The back-illuminated CMOS imaging device is a CMOS imaging device in which a light receiving unit is arranged above a circuit unit and which is higher in sensitivity and lower in noise than a front-illuminated CMOS imaging device.

The first semiconductor substrate 21 includes a protective film 30, a lens resin film 32 where an uneven structure 31 is formed, a light shielding film 34, a semiconductor layer 36, and a multilayer wiring layer 38. The protective film 30 is, for example, an oxide film, and functions as a protective film for the lens resin film 32.

In the lens resin film 32, the uneven structure 31 is formed. A flat region A104 is formed on a peripheral side of the region where the uneven structure 31 is formed. Note that the flat region A104 may be referred to as collet area. As described above, the protective film 30 is stacked and formed on an upper surface of the lens resin film 32. The uneven structure 31 has a hemispherical structure. This hemispherical structure serves as an on chip lens (OCL).

The light shielding film 34 is formed on an outer edge region of the semiconductor layer 36. The light shielding film 34 includes either an organic film or a metal film. That is, the light shielding film 34 includes a material having a light-shielding characteristic, such as a metal film or an organic film.

The light shielding film 34 and an outer edge region outside the light shielding film 34 constitute a first region A100 having the light shielding film 34. Furthermore, a region located inside the first region A100 is a second region A102 that is an effective pixel region. Note that the second region A102 that is an effective pixel region may include, for example, so-called dummy pixels that are not used for imaging. Note that the light shielding film 34 according to the present embodiment corresponds to a light shielding structure.

The semiconductor layer 36 includes thinned silicon. In the semiconductor layer 36, the pixel region 23 is formed in which a plurality of pixels each including a photodiode PD serving as the photoelectric converter and a plurality of pixel transistors is arranged in a two-dimensional matrix (see FIG. 2). Furthermore, pixels shielded by the light shielding film 34 are used to acquire information regarding dark current. The pixels used to acquire the information regarding dark current form a so-called optical black region.

The multilayer wiring layer 38 includes an interlayer insulating film. The interlayer insulating film includes wiring and connection wiring formed therein. With such a configuration, for example, the protective film 30 has a thickness of 110 nanometers, a width W100 in the thickness direction of the on chip lens is 2200 nanometers, a width W102 in the thickness direction of the lens resin film 32 excluding the width W100 in the thickness direction of the on chip lens is 1000 nanometers, and a width W104 in the thickness direction of the semiconductor layer 36 is 800 nanometers. Note that, in the present embodiment, the width W102 in the thickness direction of the lens resin film 32 excluding the width W100 in the thickness direction of the on chip lens may be referred to as planar width.

For example, in the second region A102, a phenomenon such as warping is suppressed. On the other hand, as illustrated in FIG. 3, the flat region A104 may suffer a phenomenon such as warping. When such a warping phenomenon occurs, the light detection element 1 exhibits an external defect.

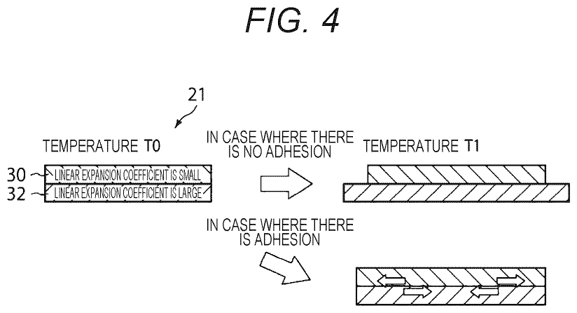

FIG. 4 is a diagram schematically illustrating a cause of the warping phenomenon. The protective film 30 has, for example, a linear expansion coefficient of 0.7, the lens resin film 32 has, for example, a linear expansion coefficient of 10 to 30, and the light shielding film 34 has, for example, a linear expansion coefficient of 1 to 10. The linear expansion coefficient of the protective film 30 is about 1/10 of the linear expansion coefficient of the lens resin film 32.

That is, a relationship of the linear expansion coefficient of the lens resin film 32>the linear expansion coefficient of the light shielding film 34>the linear expansion coefficient of the protective film 30 holds true.

Therefore, in a case where there is no adhesion between the protective film 30 and the lens resin film 32, almost no stress is generated. On the other hand, in the light detection element 1 according to the present embodiment, stress causes the protective film 30 and the lens resin film 32 to undergo distortion or unevenness, which brings about a warping phenomenon. In general, the stress is represented by Formula (1).

$$Stress = linear expansion linear expansion coefficient \times temperature difference \times Young ' s modulus \times cross - sectional area \qquad ( 1 )$$

### (Configuration Example 1)

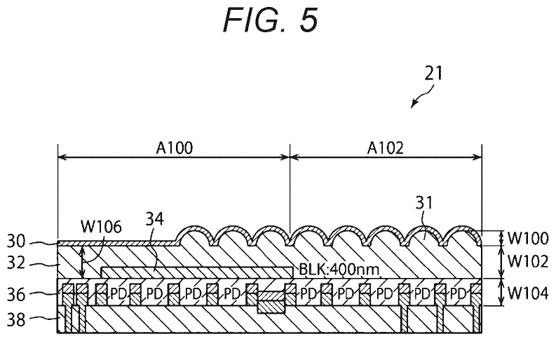

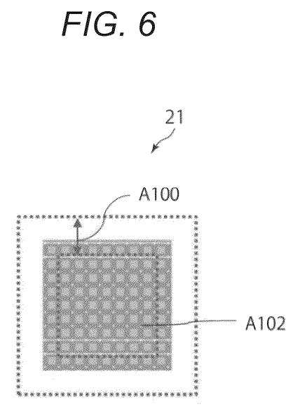

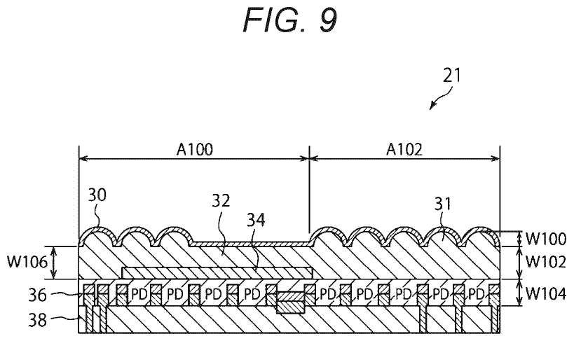

FIG. 5 is a diagram illustrating a configuration example 1 of the light detection element 1 intended to reduce stress. FIG. 6 is a diagram schematically illustrating a top view of a first semiconductor substrate 21. As illustrated in FIGS. 5 and 9, in the configuration example 1 of the light detection element 1, the uneven structure 31 extends to the first region A100 having the light shielding film 34. As described above, in the lens resin film 32 of the first region A100, the flat region and the uneven structure 31 are formed.

A semicircular structure of the uneven structure 31 can disperse stress applied to the protective film 30 and the lens resin film 32. It is therefore possible for the region where the uneven structure 31 is formed to reduce stress to such a level where no warping phenomenon appears on the exterior. Furthermore, the light shielding film 34 is formed across the region where the uneven structure 31 of the first region A100 having the light shielding film 34 is formed. This configuration makes the lens resin film 32 less in thickness than the region A102, so that the cross-sectional area of the lens resin film 32 can be further reduced, thereby further reducing stress. It is therefore possible to further suppress a warping phenomenon. As described above, the uneven structure 31 located above the light shielding film 34 is less in width in the thickness direction than the uneven structure 31 of the second region A102, so that stress applied to the protective film 30 and the lens resin film 32 is further reduced.

Moreover, in the configuration example 1 of the light detection element 1, a width W106 in the thickness direction of the flat region of the first region A100 having the light shielding film 34 is reduced to such a level where no warping phenomenon appears on the exterior. For example, the width W106 in the thickness direction of the lens resin film 32 is made less than the width W102 in the thickness direction. That is, the planar width W106 of the first region A100 having the light shielding film 34 is made less than the planar width W102 of the region A102. As described above, reducing the cross-sectional area of the lens resin film 32 makes it possible to reduce stress to such a level where no warping phenomenon appears on the exterior.

### (Configuration Example 2)

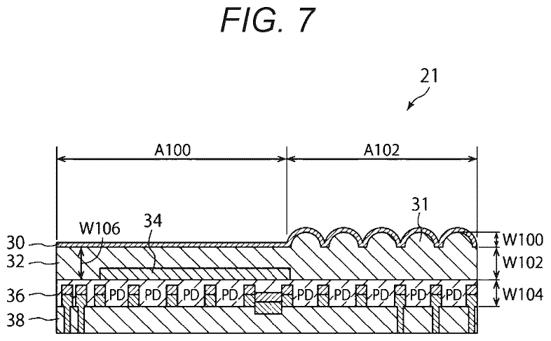

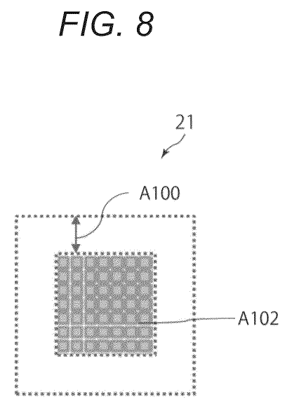

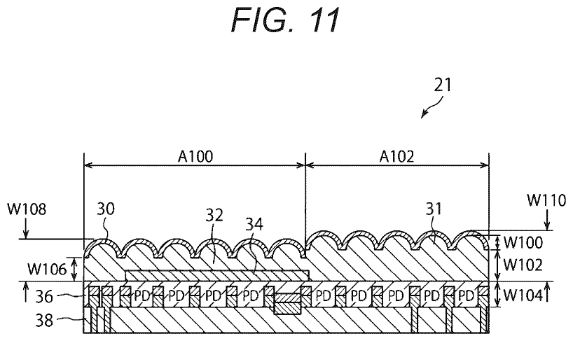

FIG. 7 is a diagram illustrating a configuration example 2 the light detection element 1. FIG. 8 is a diagram schematically illustrating a top view of a first semiconductor substrate 21 of the configuration example 2. As illustrated in FIGS. 7 and 11, in the configuration example 2 of the light detection element 1, the entire first region A100 having the light shielding film 34 is a flat region. That is, in the configuration example 2 of the light detection element 1, the width W106 in the thickness direction of the flat region of the first region A100 having the light shielding film 34 is reduced to such a level where no warping phenomenon appears on the exterior. For example, the width W106 in the thickness direction of the lens resin film 32 is made less than the width W104 in the thickness direction. As described above, reducing the cross-sectional area of the lens resin film 32 makes it possible to reduce stress to such a level where no warping phenomenon appears on the exterior. Moreover, since the width of the light shielding film 34 makes the width W106 in the thickness direction of the lens resin film 32 smaller, the cross-sectional area of the lens resin film 32 can be further reduced.

### (Configuration Example 3)

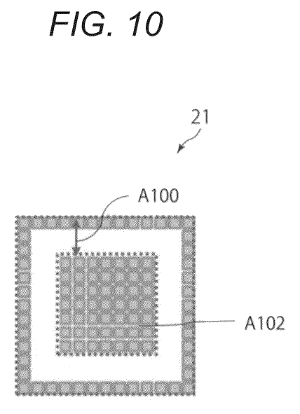

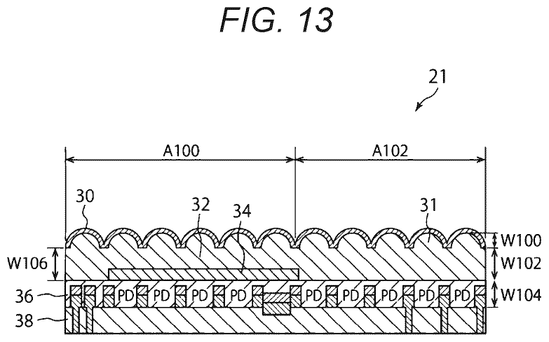

FIG. 9 is a diagram illustrating a configuration example 3 of the light detection element 1 intended to reduce stress. FIG. 10 is a diagram schematically illustrating a top view of a first semiconductor substrate 21 of the configuration example 3. As illustrated in FIGS. 9 and 13, in the configuration example 3 of the light detection element 1, the uneven structure 31 is formed on an outer edge side of the first region A100 having the light shielding film 34. It is therefore possible for the region where the uneven structure 31 is formed to reduce stress to such a level where no warping phenomenon appears on the exterior.

Furthermore, the light shielding film 34 is formed in the flat region of the first region A100 having the light shielding film 34. This configuration makes the thickness of the flat region of the lens resin film 32 less than the width W102 in the thickness direction of the region A102, so that the cross-sectional area of the lens resin film 32 can be further reduced, thereby further reducing stress. It is therefore possible to reduce stress to such a level where no warping phenomenon appears on the exterior.

### (Configuration Example 4)

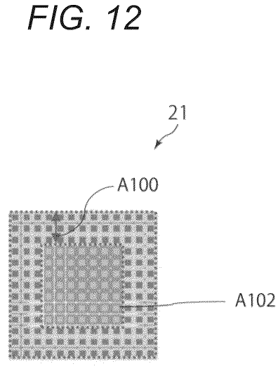

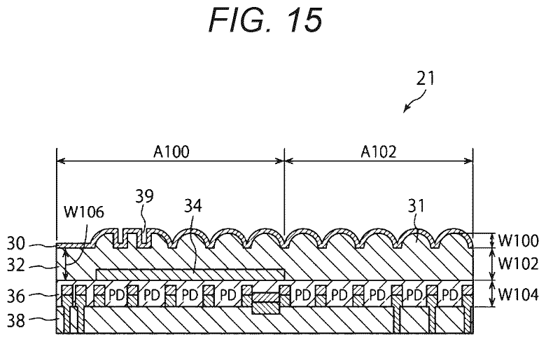

FIG. 11 is a diagram illustrating a configuration example 4 of the light detection element 1 intended to reduce stress. FIG. 12 is a diagram schematically illustrating a top view of a first semiconductor substrate 21 of the configuration example 4. As illustrated in FIGS. 11 and 15, in the configuration example 3 of the light detection element 1, the uneven structure 31 is formed all across the first region A100 having the light shielding film 34. Furthermore, a width W108 in the thickness direction of the first region A100 including the uneven structure 31 is less than a width W110 in the thickness direction of the region A102 including the uneven structure 31. As described above, in the configuration example 4, the lens resin film 32 of the first region A100 is made lower in height than the lens resin film 32 of the second region A102.

It is therefore possible for the region where the uneven structure 31 is formed to reduce stress to such a level where no warping phenomenon appears on the exterior. Furthermore, since the width W108 of the first region A100 including the uneven structure 31 is made less than the width W110 of the region A102 including the uneven structure 31, the cross-sectional area of the lens resin film 32 can be further reduced. Moreover, since the width of the light shielding film 34 makes the width W106 in the thickness direction of the lens resin film 32 smaller, the cross-sectional area of the lens resin film 32 can be further reduced.

### (Configuration Example 5)

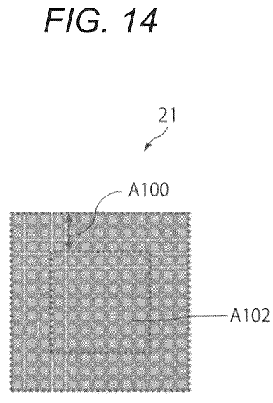

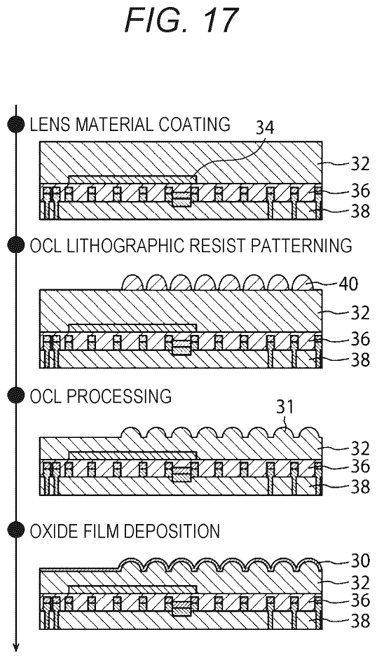

FIG. 13 is a diagram illustrating a configuration example 5 of the light detection element 1 intended to reduce stress. FIG. 14 is a diagram schematically illustrating a top view of a first semiconductor substrate 21 of the configuration example 5. As illustrated in FIGS. 13 and 17, in the configuration example 3 of the light detection element 1, the uneven structure 31 is formed all across the first region A100 having the light shielding film 34. A semicircular structure of the uneven structure 31 can disperse stress applied to the protective film 30 and the lens resin film 32. It is therefore possible for the region where the uneven structure 31 is formed to reduce stress to such a level where no warping phenomenon appears on the exterior. Furthermore, since the first region A100 and the region A102 both including the uneven structure 31 have the same thickness, the production process can be further simplified.

### (Configuration Example 6)

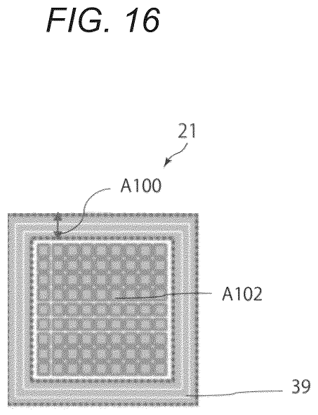

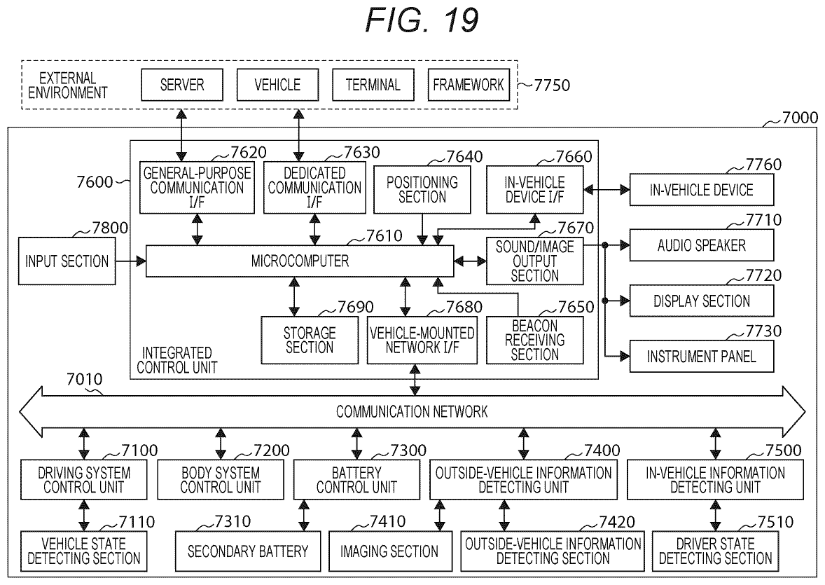

FIG. 15 is a diagram illustrating a configuration example 6 of the light detection element 1 intended to reduce stress. FIG. 16 is a diagram schematically illustrating a top view of a first semiconductor substrate 21 of the configuration example 6. As illustrated in FIGS. 15 and 19, in the configuration example 1 of the light detection element 1, the uneven structure 31 extends to the first region A100 having the light shielding film 34. Moreover, a second uneven structure having a groove 39 that is a structure different from the uneven structure 31 is formed outside the uneven structure 31.

A semicircular structure of the uneven structure 31 can disperse stress applied to the protective film 30 and the lens resin film 32. Similarly, the second uneven structure can disperse stress applied to the protective film 30 and the lens resin film 32. It is therefore possible for the region where the second uneven structure and the uneven structure 31 are formed to reduce stress to such a level where no warping phenomenon appears on the exterior. Moreover, the light shielding film 34 is formed in a region where the uneven structure 31 of the first region A100 having the light shielding film 34 is formed. This configuration makes the lens resin film 32 less in thickness than the region A102, so that the cross-sectional area of the lens resin film 32 can be further reduced, thereby further reducing stress.

Moreover, in the configuration example 1 of the light detection element 1, the width W106 in the thickness direction of the flat region of the first region A100 having the light shielding film 34 is reduced to such a level where no warping phenomenon appears on the exterior. For example, the width W106 in the thickness direction of the lens resin film 32 is made less than the width W104 in the thickness direction. As described above, reducing the cross-sectional area of the lens resin film 32 makes it possible to reduce stress to such a level where no warping phenomenon appears on the exterior.

### [Production Example 1 of Oxide Film and Lens Resin Film]

FIG. 17 is a cross-sectional view of the protective film 30 and the lens resin film 32 during their forming step. As illustrated in FIG. 17, the lens resin film 32 is formed after the light shielding film 34, the semiconductor layer 36, and the multilayer wiring layer 38 are formed. Next, a lithographic resist pattern 40 for the uneven structure 31 is formed. Note that it is possible to form, by changing the lithographic resist pattern 40, the flat region and the uneven structure 31 corresponding to each of the above-described configuration examples 1 to 6.

Next, the uneven structure 31 including the lens resin film 32 is formed by etch-back until the lithographic resist pattern 40 disappears. Through this etch-back, the shape of the lithographic resist pattern 40 is transferred to form the uneven structure 31. Then, the protective film 30 is formed by, for example, a thermal CVD device.

### [Production Example 2 of Oxide Film and Lens Resin Film]

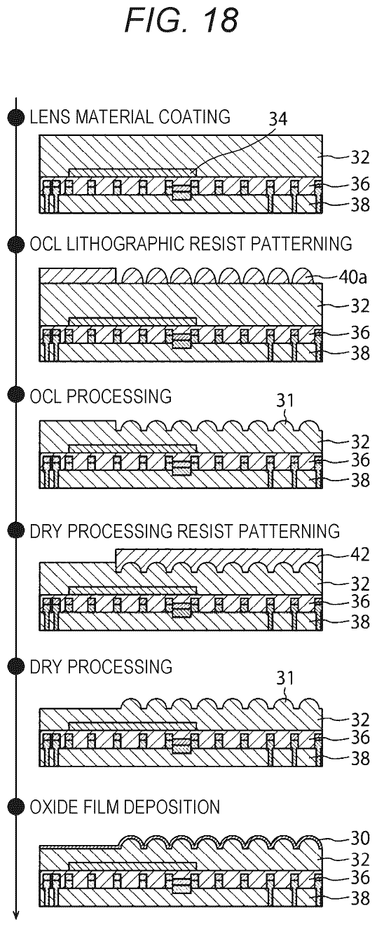

FIG. 18 is a cross-sectional view illustrating a production example 2 of the forming step of forming the protective film 30 and the lens resin film 32. As illustrated in FIG. 18, the lens resin film 32 is formed after the light shielding film 34, the semiconductor layer 36, and the multilayer wiring layer 38 are formed. Next, a lithographic resist pattern 40a for the flat region and the uneven structure 31 is formed. Note that it is possible to form, by changing the lithographic resist pattern 40a, the flat region and the uneven structure 31 corresponding to each of the above-described configuration examples 1 to 6.

Next, the uneven structure 31 including the lens resin film 32 is formed by etch-back until the lithographic resist pattern 40a disappears. Through this etch-back, the shape of the lithographic resist pattern 40 is transferred to form the uneven structure 31. Next, a dry processing resist pattern 42 is formed. Note that it is possible to form, by changing the resist pattern 42, the flat region corresponding to each of the above-described configuration examples 1 to 6.

Next, dry processing is performed until the resist pattern 42 disappears. Through this dry processing, the flat region is formed. Then, the protective film 30 is formed by, for example, a thermal CVD device.

As described above, according to the present embodiment, the light detection element 1 includes the first first region A100 having the light shielding film 34 and located on the outer edge side and the second region A102 having the photoelectric converter PD but not having the light shielding film 34, and in the lens resin film 32 of the first first region A100, at least one of the flat region less in width in the thickness direction than the lens resin film 32 of the second region A102 and the uneven structure 31 is formed. This configuration can reduce stress applied to the protective film 30 and the lens resin film 32 and suppress a warp in the protective film 30 and the lens resin film 32.

### <<Application Example>>

The technology according to the present disclosure can be applied to various products. For example, the technology according to the present disclosure may also be implemented as a device mounted on any kind of mobile body such as an automobile, an electric vehicle, a hybrid electric vehicle, a motorcycle, a bicycle, a personal mobility, an airplane, a drone, a vessel, a robot, a construction machine, an agricultural machine (tractor), or the like.

FIG. 19 is a block diagram illustrating an example of schematic configuration of a vehicle control system 7000 as an example of a mobile body control system to which the technology according to the present disclosure can be applied. The vehicle control system 7000 includes a plurality of electronic control units connected to each other via a communication network 7010. In the example illustrated in FIG. 19, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. Functional components of the integrated control unit 7600 illustrated in FIG. 19 include a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

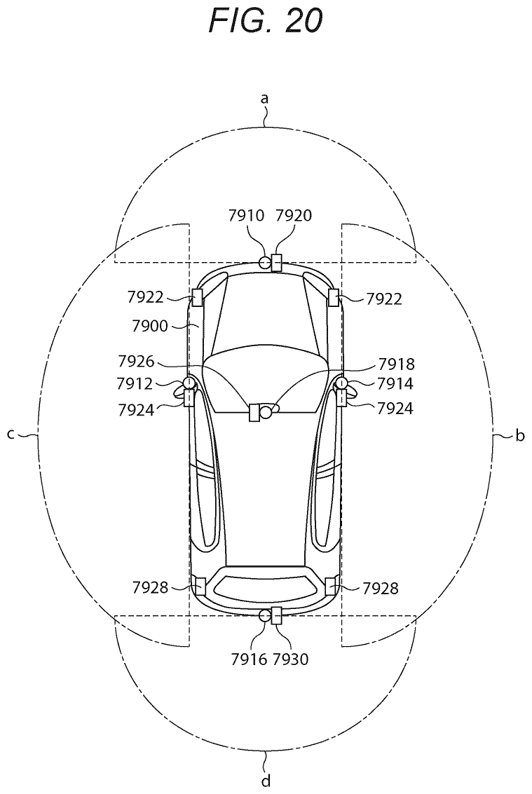

Here, FIG. 20 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 20 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 19, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 19, an audio speaker 7710, a display section 7720, and an instrument panel 7730 are illustrated as examples of the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that at least two control units connected to each other via the communication network 7010 in the example illustrated in FIG. 19 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the light detection element 1 according to the present embodiment described with reference to FIG. 1 can be implemented in any of the control units or the like. Furthermore, a computer-readable recording medium in which such a computer program is stored can be provided. The recording medium is, for example, a magnetic disk, an optical disc, a magneto-optical disk, a flash memory, or the like. Furthermore, the computer program described above may be distributed via, for example, a network without using a recording medium.

In the vehicle control system 7000 described above, the light detection element 1 according to the present embodiment described with reference to FIG. 1 can be applied to the integrated control unit 7600 of the application example illustrated in FIG. 19. For example, a sensor unit of the imaging section 7410 corresponds to the light detection element 1.

Furthermore, at least some of the components of the light detection element 1 described with reference to FIG. 1 may be implemented in a module (for example, an integrated circuit module constituted by one die) for the integrated control unit 7600 illustrated in FIG. 19. Alternatively, the light detection element 1 described with reference to FIG. 1 may be implemented by a plurality of control units of the vehicle control system 7000 illustrated in FIG. 19.

Note that the present technology may have the following configurations.

(1)

A light detection element including:
a semiconductor layer in which a plurality of pixels each including a photoelectric converter is formed;
a light shielding structure provided on an outer edge region of the semiconductor layer;
a lens resin film stacked on the semiconductor layer and the light shielding structure; and
a protective film stacked on the lens resin film,
in which a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.
   (2)

The light detection element according to (1), in which in a case where the lens resin film of the first region includes the uneven structure, a width in the thickness direction of the lens resin film including the uneven structure of the first region is made less than a width in the thickness direction of the lens resin film including the uneven structure of the second region.

(3)

The light detection element according to (1), in which the uneven structure has a hemispherical structure.

(4)

The light detection element according to (3), in which the hemispherical structure includes an on chip lens.

(5)

The light detection element according to (1), in which the uneven structure has a groove.

(6)

The light detection element according to (1), in which the lens resin film of the first region includes the flat region and the uneven structure.

(7)

The light detection element according to (6), in which the lens resin film of the first region includes the flat region formed on an outer edge side of the uneven structure.

(8)

The light detection element according to (6), in which the lens resin film of the first region includes the flat region formed at a side of the second region of the uneven structure.

(9)

The light detection element according to (6), in which the flat region and the uneven structure are formed above the light shielding structure.

(10)

The light detection element according to (9), in which the flat region is formed at a side of the second region of the uneven structure above the light shielding structure.

(11)

The light detection element according to (9), in which the flat region is formed on an outer edge side of the uneven structure above the light shielding structure.

(12)

The light detection element according to (1), in which in a case where the lens resin film of the first region includes the flat region, a planar width of the flat region in the lens resin film of the first region is made less than a planar width excluding a width of the uneven structure of the lens resin film of the second region.

(13)

The light detection element according to (1), in which a width in the thickness direction of the lens resin film of the first region is made greater than a width in the thickness direction of the light shielding structure, and the width in the thickness direction of the light shielding structure is made greater than a width in the thickness direction of the protective film.

(14)

The light detection element according to (1),
in which the light shielding structure includes a material having a light shielding characteristic such as a metal film or an organic film, and
the protective film includes an oxide film.
   (15)

The light detection element according to (1), in which a linear expansion coefficient of the lens resin film of the first region is different from a linear expansion coefficient of the protective film.

(16)

The light detection element according to (1), in which pixels of the second region include dummy pixels that are not used for imaging.

(17)

The light detection element according to (1), in which pixels of the first region include pixels used to acquire information regarding dark current.

(18)

The light detection element according to (2), in which in the first region, a planar width of a region that is in contact with the second region is made less than a planar width on an outer edge side.

(19) An imaging device including:
a light detection element; and
an optical system that condenses light onto the light detection element,
in which the light detection element includes
a semiconductor layer in which a plurality of pixels each including a photoelectric converter is formed,
a light shielding structure provided on outer edge region of the semiconductor layer,
a lens resin film stacked on the semiconductor layer and the light shielding structure, and
a protective film stacked on the lens resin film,
a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.
   (20)

A vehicle control system including an imaging device according to (19).

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Light detection element
2 Pixel
30 Protective film
31 Uneven structure
32 Lens resin film
34 Light shielding film
36 Semiconductor layer
39 Groove
7000 Vehicle control system
A100 First region
A102 Second region

What is claimed is:

1. A light detection element, comprising:
a semiconductor layer in which a plurality of pixels each including a photoelectric converter is formed;
a light shielding structure provided on an outer edge region of the semiconductor layer;
a lens resin film stacked on the semiconductor layer and the light shielding structure; and
a protective film stacked on the lens resin film,
wherein a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.

2. The light detection element according to claim 1, wherein in a case where the lens resin film of the first region includes the uneven structure, a width in the thickness direction of the lens resin film including the uneven structure of the first region is made less than a width in the thickness direction of the lens resin film including the uneven structure of the second region.

3. The light detection element according to claim 1, wherein the uneven structure has a hemispherical structure.

4. The light detection element according to claim 3, wherein the hemispherical structure includes an on chip lens.

5. The light detection element according to claim 1, wherein the uneven structure has a groove.

6. The light detection element according to claim 1, wherein the lens resin film of the first region includes the flat region and the uneven structure.

7. The light detection element according to claim 6, wherein the lens resin film of the first region includes the flat region formed on an outer edge side of the uneven structure.

8. The light detection element according to claim 6, wherein the lens resin film of the first region includes the flat region formed at a side of the second region of the uneven structure.

9. The light detection element according to claim 6, wherein the flat region and the uneven structure are formed above the light shielding structure.

10. The light detection element according to claim 9, wherein the flat region is formed at a side of the second region of the uneven structure above the light shielding structure.

11. The light detection element according to claim 9, wherein the flat region is formed on an outer edge side of the uneven structure above the light shielding structure.

12. The light detection element according to claim 1, wherein in a case where the lens resin film of the first region includes the flat region, a planar width of the flat region in the lens resin film of the first region is made less than a planar width excluding a width of the uneven structure of the lens resin film of the second region.

13. The light detection element according to claim 1, wherein a width in the thickness direction of the lens resin film of the first region is made greater than a width in the thickness direction of the light shielding structure, and the width in the thickness direction of the light shielding structure is made greater than a width in the thickness direction of the protective film.

14. The light detection element according to claim 1,
wherein the light shielding structure includes a material having a light shielding characteristic such as a metal film or an organic film, and
the protective film includes an oxide film.

15. The light detection element according to claim 1, wherein a linear expansion coefficient of the lens resin film of the first region is different from a linear expansion coefficient of the protective film.

16. The light detection element according to claim 1, wherein pixels of the second region include dummy pixels that are not used for imaging.

17. The light detection element according to claim 1, wherein pixels of the first region include pixels used to acquire information regarding dark current.

18. The light detection element according to claim 2, wherein in the first region, a planar width of a region that is in contact with the second region is made less than a planar width on an outer edge side.

19. An imaging device, comprising:
a light detection element; and
an optical system that condenses light onto the light detection element,
wherein the light detection element includes
a semiconductor layer in which a plurality of pixels each including a photoelectric converter is formed,
a light shielding structure provided on an outer edge region of the semiconductor layer,
a lens resin film stacked on the semiconductor layer and the light shielding structure, and
a protective film stacked on the lens resin film,
a first region located on an outer edge side and having the light shielding structure, and a second region having the photoelectric converter but not having the light shielding structure are provided, and
the lens resin film of the first region is formed with at least one of a flat region less in width in a thickness direction than the lens resin film of the second region and an uneven structure.

20. A vehicle control system comprising an imaging device according to claim 19.
